(19) United States
(12) Patent Application Publication
(10) Pub. No.: US 2013/0280873 A1
(43) Pub. Date: Oct. 24, 2013

(54) ENHANCED DEVICE RELIABILITY OF A SEMICONDUCTOR DEVICE BY PROVIDING SUPERIOR PROCESS CONDITIONS IN HIGH-K FILM GROWTH

(71) Applicant: GLOBALFOUNDRIES INC., Grand Cayman (KY)

(72) Inventors: Elke Erben, Dresden (DE); Martin Trentzsch, Radebeul (DE); Richard Carter, Dresden (DE); Carsten Grass, Dresden (DE)

(73) Assignee: GLOBALFOUNDRIES INC., Grand Cayman (KY)

(21) Appl. No.: 13/793,401

(22) Filed: Mar. 11, 2013

(30) Foreign Application Priority Data
Apr. 18, 2012 (DE) 10 2012 206 405.2

(51) Int. Cl. H01L 21/02; H01L 29/66

(52) U.S. Cl. CPC H01L 21/02181; H01L 29/66477; H01L 28/40
USPC 438/239; 438/381; 438/703

(57) ABSTRACT

When forming sophisticated circuit elements, such as transistors, capacitors and the like, using a combination of a conventional dielectric material and a high-k dielectric material, superior performance and reliability may be achieved by forming a hafnium oxide-based high-k dielectric material on a conventional dielectric layer with a preceding surface treatment, for instance using APM at room temperature. In this manner, sophisticated transistors of superior performance and with improved uniformity of threshold voltage characteristics may be obtained, while also premature failure due to dielectric breakdown, hot carrier injection and the like may be reduced.

### BACKGROUND OF THE INVENTION

1. Field of the Invention

Generally, the present disclosure relates to integrated circuits including advanced circuit elements, such as transistors, capacitors and the like, that comprise highly capacitive structures including a high-k gate dielectric, such as high-k metal gate structures.

2. Description of the Related Art

The fabrication of advanced integrated circuits, such as CPUs, storage devices, ASICs (application specific integrated circuits) and the like, requires a large number of circuit elements to be formed on a given chip area according to a specified circuit layout, wherein field effect transistors represent one important type of circuit element that substantially determines performance of the integrated circuits. Generally, a plurality of process technologies are currently practiced, wherein, for many types of complex circuitry, including field effect transistors, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as channel length. Hence, the conductivity of the channel region substantially affects performance of MOS transistors, thereby making the reduction of the gate length a dominant design criterion for accomplishing an increase in the operating speed of the integrated circuits.

Presently, the vast majority of integrated circuits are fabricated on the basis of silicon, due to the substantially unlimited availability thereof, the well-understood characteristics of silicon and related materials and processes and the experience gathered over the last 50 years. Therefore, silicon will likely remain the material of choice in the foreseeable future for circuit generations designed for mass products. One reason for the importance of silicon for fabricating semiconductor devices has been the superior characteristics of a silicon/silicon dioxide interface that allows reliable electrical insulation of different regions from each other. The silicon/silicon dioxide interface is stable at high temperatures and, thus, allows the performance of subsequent high temperature processes, as are required, for example, for anneal cycles to activate dopants and to cure crystal damage, without sacrificing the electrical characteristics of the interface.

For the reasons pointed out above, in field effect transistors, silicon dioxide-based dielectric materials are preferably used as a gate insulation layer that separates the gate electrode, frequently comprised of polysilicon or metal-containing materials, from the silicon channel region. In steadily improving device performance of field effect transistors, the length of the channel region has been continuously decreased to improve switching speed and drive current capability. Since the transistor performance is controlled by the voltage supplied to the gate electrode to invert the surface of the channel region to a sufficiently high charge carrier density for providing the desired drive current for a given supply voltage, a certain degree of capacitive coupling, provided by the capacitor formed by the gate electrode, the channel region and the silicon dioxide disposed therebetween, has to be maintained. It turns out that decreasing the channel length requires an increased capacitive coupling to avoid the so-called short channel behavior during transistor operation. Aggressively scaled transistor devices with a relatively low supply voltage and thus reduced threshold voltage may suffer from an exponential increase of the leakage current due to the required enhanced capacitive coupling of the gate electrode to the channel region that is accomplished by decreasing the thickness of the silicon dioxide layer. For example, a channel length of approximately 0.08 μm may require a gate dielectric made of silicon dioxide as thin as approximately 1.2 nm.

In such advanced transistor elements, reliability, and thus lifetime, significantly depends on short channel effects, i.e., impact ionization and hot carrier injection into the gate dielectric material, while also gate leakage currents may significantly increase when using silicon dioxide-based gate dielectrics of a reduced thickness. For example, since device dimensions have been scaled down more rapidly compared to the supply voltages, the resulting electrical field strengths in the gate dielectric material have significantly increased, while at the same time the threshold voltage of the transistors, i.e., the voltage at which a conductive channel forms in the channel region, has been reduced in order to improve drive current and switching speed of sophisticated transistors. Consequently, the quality of the gate dielectric material may strongly influence the transistor behavior, while at the same time a high stability of the threshold voltage of the transistor is required over the rated lifetime in order to fulfill the device qualifications.

Upon further scaling the critical dimensions of transistor elements, a further long-known effect may increasingly play an important role for CMOS devices when threshold voltages and, to a less pronounced degree, also the supply voltages are steadily reduced. It has been observed in the late '60s that the application of voltage, such as a negative voltage, in combination with thermal stress to the gate electrode of MOS transistors may result in a shift of the threshold voltage. This effect, also referred to as “bias temperature instability or injection” is mainly present in PMOS transistors but also significantly affects NMOS transistors and was not considered particularly relevant for semiconductor devices in the following years due to the low influence on the overall device performance of devices, in particular as NMOS devices have increasingly been developed. This situation changed with the introduction of complex CMOS devices including high performance logic circuits in which millions of signal nodes with PMOS and NMOS transistors are typically provided. In these devices, the threshold voltage and the supply voltage have constantly been reduced, while, on the other hand, the electric field strengths across the gate dielectrics have increased. Under such conditions, a change of the threshold voltage may have an even higher impact since transistor operation variability may increase due to the relatively higher influence of a shift of the threshold voltage. Furthermore, the operating states of the transistors resulting in the application of voltage pulses, such as negative and positive voltages, to the gate electrode of MOS transistors may depend on the signal path considered and the overall operational conditions, thereby resulting in substantially non-predictable threshold shifts within the lifetime of the device. For example, a shift of the threshold voltage over the accumulated operating time may finally lead to a violation of time specifications of the device, which may not allow a further use of the device despite the fact that no other major failure has occurred.

Generally, this effect is also associated with the quality of the gate dielectric material and, in particular, with the quality of the interface between the semiconductor material in the channel region and the gate dielectric material. In this case, upon certain operational conditions, such as elevated temperatures and other stress conditions, a charge trap is created in the vicinity of the interface, wherein, in particular, holes may be trapped thereby resulting in a significant shift of threshold voltage by localized positive interface states and the additionally trapped charges.

In view of reducing short channel effects and undesired gate leakage currents, the replacing of silicon dioxide or at least a portion thereof as the material for gate insulation layers has been considered. Possible alternative dielectric material include materials that exhibit a significantly higher permittivity so that a physically greater thickness of a correspondingly formed gate insulation layer nevertheless provides a capacitive coupling that would be obtained by an extremely thin silicon dioxide-based material. It has, thus, been suggested to replace silicon dioxide-based materials at least partially with materials of an increased dielectric constant, such as hafnium-based dielectric materials, zirconium oxide and the like, wherein hafnium-based dielectric materials have become the dominant material for forming high-k dielectric materials, i.e., a dielectric material having a dielectric constant k of 10.0 or higher. Hafnium dioxide-based materials exhibit superior material characteristics in terms of k-value, thermal stability, physical scaling and the like, while also integration in the CMOS process with respect to interface control, etch chemistries and the like is superior compared to other high-k candidates. In some conventional approaches, a “conventional” gate dielectric material, such as silicon dioxide, silicon oxynitride and the like, is formed on the semiconductor material of the channel region, followed by the high-k dielectric material, which may then be capped by an appropriate conductive material, such as titanium nitride, tantalum nitride and the like, in combination with an appropriate metal species, such as lanthanum, aluminum and the like, in order to adjust the work function as may be required for N-channel transistors and P-channel transistors, respectively. In some conventional approaches, an additional adaptation of the electronic configuration of the semiconductor material in the channel region with respect to the work function may be required, which may be accomplished by providing an appropriate semiconductor material in order to obtain the required band gap offset. For this purpose, in the P-channel transistor, a silicon/germanium semiconductor mixture or alloy may be provided with a specific thickness and germanium concentration in order to obtain the required band gap offset and thus a desired threshold voltage of the P-channel transistor.

Although the usage of high-k gate dielectric materials may enable a further scaling of the channel length of critical transistors, it turns out, however, that significant threshold voltage instabilities and reduced reliability of the high-k dielectric gate materials may result in a significantly reduced production yield and premature failure of sensitive electronic devices. Without intending to restrict the present application to the following explanation, it is believed that the interface characteristics of an interface formed between the silicon dioxide-based dielectric material and the hafnium-based high-k dielectric material may play an important role with respect to breakdown voltage, threshold voltage shift and the like. For example, upon further scaling the overall device dimensions, the characteristics of the interfacial area between the conventional dielectric material and the high-k dielectric material may increasingly dominate the overall performance and reliability behavior of sophisticated gate electrode structures. On the other hand, hafnium-based gate dielectric materials may still play a major role in future device generations due to the superior material characteristics of hafnium-based high-k dielectric materials.

In view of the situation described above, the present disclosure relates to manufacturing techniques in forming high-k dielectric materials on the basis of hafnium in sophisticated semiconductor devices, while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure generally provides manufacturing techniques for forming a dielectric material system or layer in sophisticated semiconductor devices on the basis of a conventional dielectric material, such as silicon dioxide, nitrogen-containing silicon dioxide and the like, in combination with a hafnium-based high-k dielectric material. It has been recognized that the characteristics of an interface formed between the dielectric layer of conventional configuration and the hafnium-based high-k dielectric material may be significantly improved during a cyclic deposition process, such as an atomic layer deposition (ALD) process, by adjusting surface conditions of the conventional dielectric material prior to performing the first cycle of the cyclic deposition process. Without intending to restrict the present disclosure to the following explanation, it is believed that the formation of a hafnium oxide material on the basis of an ALD process may result in superior interfacial characteristics by taking into consideration the presence of OH groups prior to performing the first hafnium deposition cycle, wherein a corresponding preparation or conditioning of the exposed surface of the conventional dielectric material may be applied on the basis of an appropriate wet chemical treatment. For example, in some illustrative embodiments disclosed herein, ammonium hydroxide and hydrogen peroxide may be used in combination so as to provide superior surface conditions. In this manner, overall stability of the interface between the conventional dielectric material and the hafnium oxide-based high-k dielectric material may improve, for instance with respect to subsequent high temperature processes, while also the leakage current behavior for a given overall thickness may be enhanced. In other cases, generally the characteristics of capacitive structures, such as capacitors and the like, may be significantly improved in terms of performance and overall reliability.

One illustrative method disclosed herein comprises forming a first dielectric layer on a semiconductor region of a semiconductor device. The method further comprises performing a surface treatment on the first dielectric layer by using a mixture of ammonium hydroxide and hydrogen peroxide so as to prepare a surface of the first dielectric layer for a subsequent deposition of a second dielectric layer based on hafnium oxide. Additionally, the method comprises forming the second dielectric layer on the prepared surface by applying a cyclic deposition process.

A further illustrative method disclosed herein comprises forming an oxide-based dielectric layer on an active region of a transistor of a semiconductor device. Furthermore, the method comprises preparing a surface of the oxide-based dielectric layer for a subsequent deposition of a hafnium oxide-based high-k dielectric material by performing a wet chemical treatment so as to increase a number of OH groups at the surface. The method further comprises forming the hafnium oxide-based high-k dielectric material by a cyclic deposition process. Moreover, the method comprises forming a gate electrode structure of the transistor by forming at least one electrode material above the hafnium oxide-based high-k dielectric material.

A still further illustrative method disclosed herein relates to forming a gate dielectric material of a transistor. The method comprises forming an oxide-based dielectric material on an active region of the transistor. Moreover, a surface of the oxide-based dielectric material is prepared by applying a wet chemical process based on ammonium hydroxide and hydrogen peroxide. Moreover, the method comprises forming a hafnium oxide layer on the prepared surface while suppressing incorporation of non-hafnium species and non-oxygen species.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a semiconductor device during the formation of a “conventional” dielectric material as a part of a sophisticated high-k dielectric layer or layer system, according to illustrative embodiments;

FIG. 1b schematically illustrates the semiconductor device during a surface treatment for appropriately preparing an exposed surface of the previously formed dielectric material for a subsequent deposition of a hafnium-based high-k dielectric material, according to illustrative embodiments;

FIGS. 1c-1f schematically illustrate cross-sectional views of the semiconductor device during various cycles of an ALD process so as to form a hafnium oxide-based high-k dielectric material, according to illustrative embodiments;

FIG. 1g schematically illustrates a cross-sectional view of the semiconductor device with a dielectric layer or material system comprising a conventional dielectric material and a hafnium oxide-based high-k dielectric material with superior interface characteristics, according to illustrative embodiments;

FIGS. 2a-2c schematically illustrate cross-sectional views of a semiconductor device during various manufacturing stages in forming a transistor comprising a gate electrode structure that is formed on the basis of a process sequence as described above with reference to FIGS. 1a-1f;

FIGS. 3a-3d schematically illustrate cross-sectional views of a semiconductor device during various manufacturing stages in forming a gate electrode structure on the basis of a superior high-k dielectric material according to a replacement gate approach, according to further illustrative embodiments; and

FIGS. 4a and 4b schematically illustrate measurement results obtained from conventionally fabricated transistors and transistors formed on the basis of a gate electrode structure including a superior high-k dielectric material according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure provides manufacturing techniques for sophisticated high-k dielectric layers or material systems, for instance for use in capacitive structures, such as electrode structures and the like, wherein a hafnium oxide-based high-k dielectric material may be formed on a “conventional” dielectric material, such as silicon dioxide, nitrogen-enriched silicon dioxide and the like. To this end, it has been recognized that the characteristics of an interface formed between these two materials may be significantly improved by applying an appropriate surface treatment prior to the deposition of the hafnium oxide-based dielectric material. To this end, in some illustrative embodiments, a mixture of ammonium hydroxide and hydrogen peroxide (APM) may be used during a wet chemical surface treatment, thereby efficiently preparing the exposed surface of the underlying dielectric layer for the subsequent deposition of the hafnium oxide-based material. Appropriate mixtures of the above-specified components may be readily prepared on the basis of available recipes, since APM may frequently be used in other manufacturing stages in order to provide a clean surface, for instance of semiconductor regions and the like. In some illustrative embodiments, a process temperature of the surface treatment, i.e., a temperature of the surface to be treated as well as a temperature of the process environment in which the surface treatment may be performed, may be adjusted to a relatively low temperature, for instance approximately at room temperature, while in other cases a temperature range of 10-40° C. or 15-30° C. may be efficiently applied. Without intending to restrict the present disclosure to the following statements, it is believed that a surface treatment increasing the amount of available OH groups immediately prior to the first deposition cycle for depositing a hafnium oxide material may result in a superior two-dimensional growth of the hafnium oxide material compared to conventional strategies in which any such surface preparation on the basis of a wet chemical treatment, for instance using APM, is not used.

Moreover, in some illustrative embodiments, the cyclic deposition process may be performed on the basis of silicon-free precursor gases so as to substantially avoid the incorporation of a silicon species into the hafnium oxide-based high-k dielectric material, thereby achieving superior performance characteristics of the resulting dielectric material system. For example, frequently, a high-k dielectric material in the form of HFSION may be used in advanced semiconductor devices which, however, has been recognized according to the principles disclosed herein as less efficient. Hence, in other illustrative embodiments, in addition to avoiding the presence of a silicon-containing precursor gas, also the presence of a nitrogen-containing precursor gas may be avoided, which is to be understood such that precursor gases including silicon and/or nitrogen in the stoichiometric formula may not be used while, however, any process imperfections may nevertheless result in the presence of a certain minute amount of these atomic species. In this sense also the term “silicon-free precursor gas” or “nitrogen-free precursor gas” is to be understood.

The principles disclosed herein may thus efficiently be used in forming circuit elements such as gate electrode structures of advanced transistors, capacitors and the like, wherein improved characteristics in terms of performance and reliability may be achieved, thereby allowing a further scaling of the circuit elements under consideration.

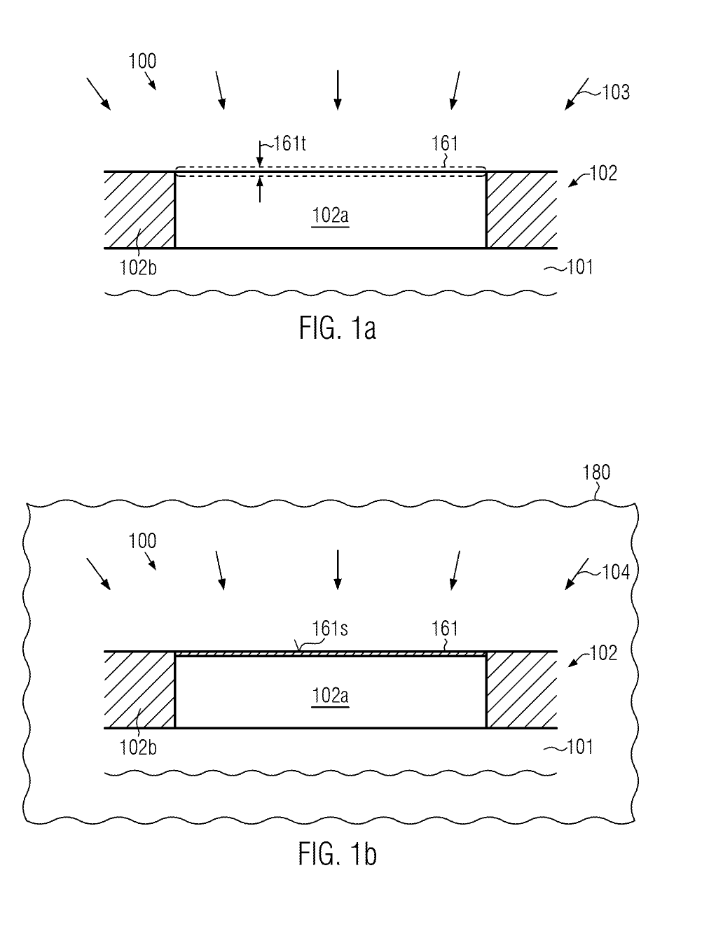

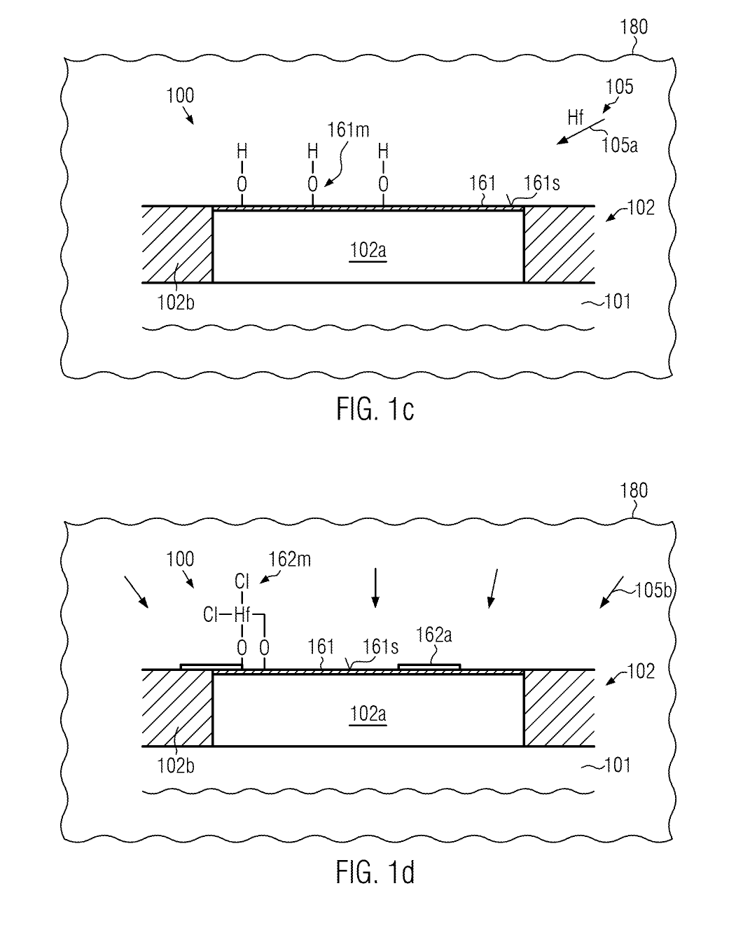

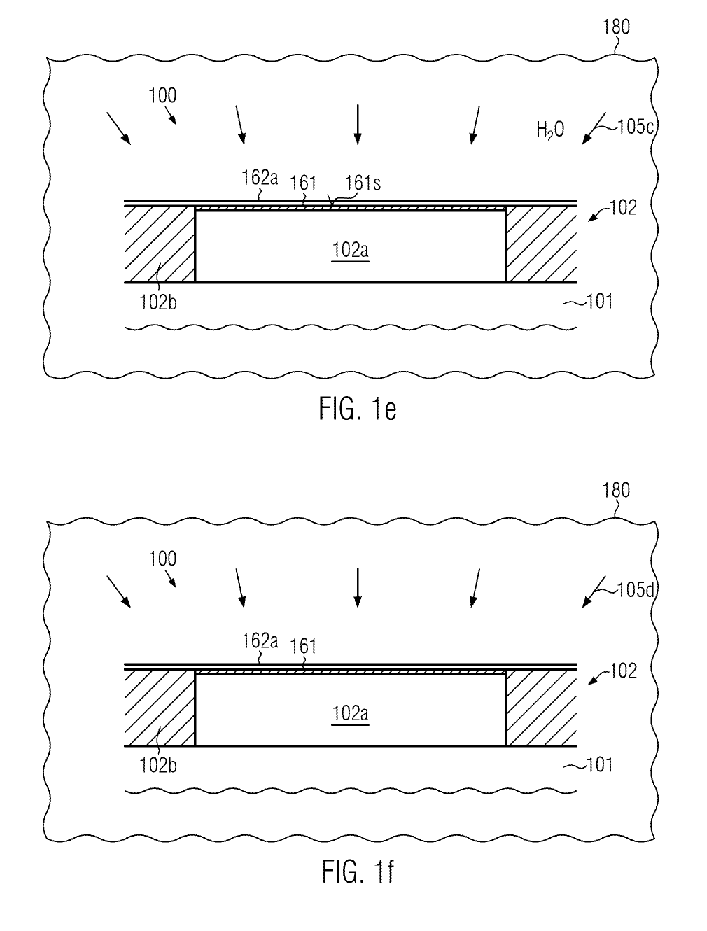

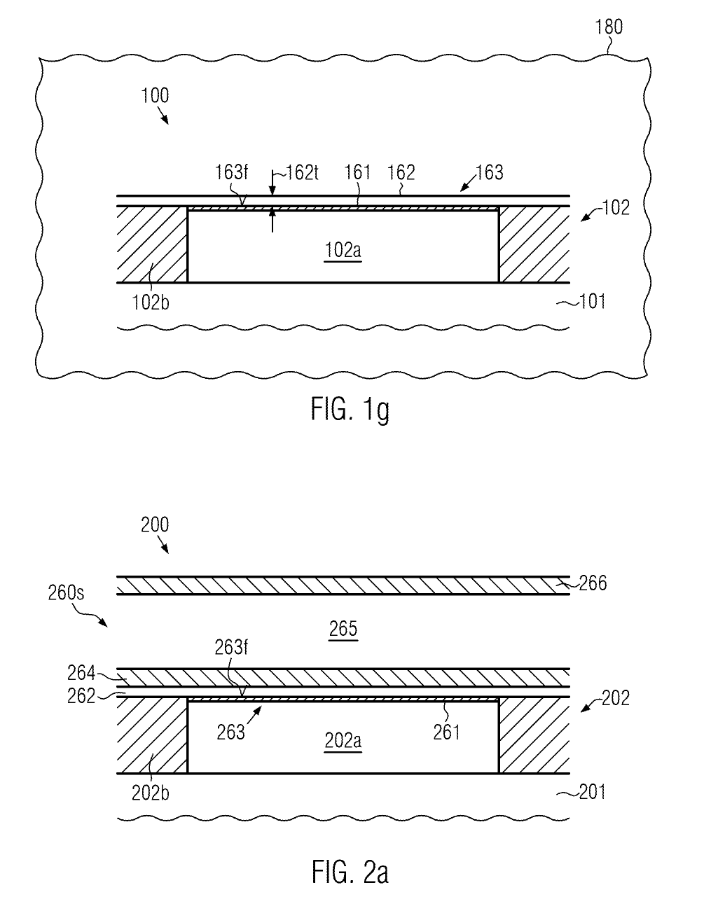

FIG. 1a schematically illustrates a cross-sectional view of a semiconductor device 100 in a manufacturing stage in which a semiconductor layer 102 may be formed above a substrate 101, which may represent any appropriate carrier material for forming thereabove the semiconductor layer 102. In illustrative embodiments, the semiconductor layer 102 may represent a silicon-containing semiconductor material, such as a silicon/germanium material, a substantially pure silicon material except for the presence of dopants and the like. Moreover, it should be appreciated that the substrate 101 and the semiconductor layer 102 may form an SOI (silicon-on-insulator) configuration, at least in some areas of the device 100, if required by the overall device design. In other cases, the semiconductor layer 102 may directly connect to a crystalline semiconductor material of the substrate 101, thereby forming a bulk configuration. Furthermore, in the manufacturing stage shown, the semiconductor layer 102 may be laterally divided into a plurality of semiconductor regions or active regions, wherein, for convenience, a single active region 102a is illustrated. It should be understood that the active region 102a is to represent a semiconductor region in and above which at least one circuit element, such as a transistor or a capacitor, is to be formed. The lateral delineation of the active region 102a may be accomplished by means of an isolation structure 102b, such as a shallow trench isolation and the like. Moreover, a dielectric layer 161 may be formed on the active region 102a with any appropriate material composition and thickness so as to comply with the requirements of a dielectric material layer or system still to be formed on the basis of the layer 161.

The semiconductor device 100 as shown in FIG. 1a may be formed on the basis of the following processes. The active region 102a may be formed by introducing appropriate dopant species, for instance by epitaxial growth, implantation techniques and the like, wherein, prior to or after incorporating respective dopant species, the isolation structure 102b may be formed, for instance, by applying well-established lithography, etch, deposition, anneal and planarization techniques. For example, the isolation structure 102b may be formed on the basis of silicon dioxide, silicon nitride or any combination thereof. Thereafter, a process 103 may be applied so as to form the “conventional” dielectric layer 161 having a desired thickness 161t, which in sophisticated cases may be 1 nm and less. To this end, well-established oxidation processes are available, for instance, for forming an oxide-based dielectric material from the active region 102a, which may be comprised of silicon, while in other cases a silicon/germanium alloy may be provided, at least at a surface portion of the active region 102a. Furthermore, if required, a certain amount of nitrogen may be incorporated into the layer 161 during the process 103. In this manner, well-known characteristics of an interface between a silicon material and a silicon dioxide-based material or the interface characteristics of a silicon/germanium alloy with a corresponding oxide material may be taken advantage of upon forming a dielectric material system that has an increased dielectric constant compared to usually used dielectric materials.

FIG. 1b schematically illustrates the semiconductor device 100 within a process environment 180 that is appropriately configured for performing surface treatment 104 in order to prepare an exposed surface 161s of the dielectric layer 161. In one illustrative embodiment, the process environment 180 represents a deposition chamber which may also be used for a subsequent deposition of a hafnium oxide-based high-k dielectric material. In this manner, any additional influence of a further process atmosphere acting on the treated surface 161s may be substantially avoided. It should be appreciated, however, that, in other illustrative embodiments, the surface treatment 104 may be applied within any other appropriate process environment, as long as appropriate transportation of the device 100 to a corresponding deposition tool is ensured without undue interaction with the clean room atmosphere and the like.

The treatment 104 may be applied in the form of a wet chemical process performed so as to clean the surface 161s, for instance with respect to contaminants and the like, while also increasing the number of OH groups that are available for a surface reaction during the subsequent deposition process. In illustrative embodiments, the treatment or wet chemical process 104 may comprise the application of a mixture of ammonium hydroxide and hydrogen peroxide, which has been identified as being highly effective in providing superior growth conditions during the subsequent cyclic deposition process. To this end, a corresponding mixture may be used with appropriate mixing ratio, which may be readily determined on the basis of experiments, while in other cases well-established recipes may be used since APM is also frequently used as a cleaning agent or as a wet chemical etch chemistry in other manufacturing stages. Furthermore, in some illustrative embodiments, the process temperature within the environment 180 is adjusted to a range of 10-40° C. or 15-30° C., while in other cases the process environment 180 is thermally connected to the surroundings, thereby achieving substantially room temperature during the process 104. In this manner, a highly efficient and non-complex process control may be achieved since, upon operating at room temperature, a high degree of process robustness may be obtained. Furthermore, process time of the process 104 may also be readily determined on the basis of experiment in which process parameters, such as exposure time and mixture ratio, may be varied, while the resulting device characteristics may be measured so as to determine an appropriate set of process parameters. As will be discussed later on, appropriate performance characteristics of the resulting high-k dielectric material or material system may be readily determined on the basis of performance characteristics of transistors, capacitors and the like.

FIG. 1c schematically illustrates the semiconductor device 100 in a further advanced manufacturing stage. As shown, the device 100 may be positioned in an appropriate process environment that enables the performance of a cyclic deposition process. In the embodiment shown, the process environment 180 may be used, thereby avoiding undue transportation activities and reducing any influence of process atmospheres after having performed the surface treatment 104 of FIG. 1b. As shown, a cyclic deposition process or ALD process 105 may be applied in the environment 180, wherein a cyclic deposition process is to be understood as a process in which a CVD-like (chemical vapor deposition) deposition behavior is obtained on the basis of surface reactions, which may be more or less self-limiting, thereby enabling the deposition of a specific preliminary material layer which may subsequently be exposed to a further precursor gas component so as to form the desired material composition, wherein a plurality of such cycles may be repeated so as to obtain the finally desired layer thickness. That is, an ALD or cyclic deposition technique provides a series of self-limiting surface reactions and thus is relatively insensitive to changes in the delivery of precursor gases and the like. Furthermore, depending on the process recipe, a substantially non-activated process may be implemented, thereby also reducing temperature dependence of the resulting process. Thus, an ALD process or a cyclic deposition process results in an intrinsically high process robustness with low impurity incorporation, wherein a precise thickness control may be achieved. It has been recognized that, in addition to these characteristics of an ALD process, overall performance of the deposition process may be enhanced by applying the treatment 104 of FIG. 1b to the exposed surface 161s, thereby attaining superior growth conditions which, for instance, may result in a moderately fast closure of the growing dielectric material layer. It is believed that, in particular, the number and thus sites with reactive OH groups may be increased, thereby contributing to a fast-growing layer on the surface 161s. In a first cycle 105a of the process 105, a precursor gas may be supplied to the environment 180, which comprises hafnium, wherein the precursor may react with the prepared surface 161s so as to enable sufficient adhesion of the hafnium species to the surface 161s, for instance to the OH groups 161m contained therein. For example, hafnium chloride (HFCL₄) may be used as a precursor gas, while, however, any other precursor gases may be used, depending on the overall process strategy.

FIG. 1d schematically illustrates the device 100 during a further step of the cyclic deposition process, indicated as step 105b, in which any appropriate inert gas component may be supplied so as to purge the environment 180. As discussed above, during the preceding deposition cycle 105a of FIG. 1c, hafnium species 162m may have reacted with the surface 161s thereby forming surface portions 162a, which may be considered as a “preliminary” material layer of a high-k dielectric material still to be formed.

FIG. 1e schematically illustrates the device 100 during a further cycle or step 105c, in which an oxidant, such as H₂O and the like, may be supplied so as to form a hafnium oxide-based material on the surface 161s. Hence, in this stage, the preliminary layer portions 162a may comprise hafnium oxide, possibly in combination with other species, such as hydrogen, chlorine and the like, depending on the type of precursor gases used.

As discussed above, in some illustrative embodiments, the cycles 105a (FIG. 1c) and 105c may be performed on the basis of silicon-free and nitrogen-free precursor gases in order to efficiently suppress the incorporation of any of these species into the layer 162a.

FIG. 1f schematically illustrates the device 100 during a further step or cycle 105d, in which a purging inert gas may be supplied so as to efficiently remove any unwanted gas components. Hence, the preliminary layer or layer portions 162a may comprise hafnium oxide, while substantially no silicon species or nitrogen species may be incorporated. After, the steps or cycles as shown in FIGS. 1c-1f may be repeated so as to form a dielectric layer on the basis of hafnium oxide with a desired thickness and uniformity. Without intending to restrict the present disclosure to the following explanation, it is assumed that an increased two-dimensional growth may be achieved upon performing the cyclic deposition process 105 so that a substantially closed layer of the hafnium oxide-based dielectric material may be achieved by a reduced number of repetitions compared to conventional strategies. For example, corresponding measurements seem to indicate that a substantially closed surface, i.e., a substantially continuous layer 162a, may be obtained after approximately ten passes of the above-described cycles or steps. The superior two-dimensional growth of the layer 162a may, thus, result in superior interface characteristics with respect to the underlying layer 161, thereby imparting superior robustness to this interface during the further processing of the device 100, for instance in terms of high temperature processes and the like.

FIG. 1g schematically illustrates the semiconductor device 100 in a further advanced manufacturing stage. As illustrated, a high-k dielectric material 162, which may also be referred to as a hafnium oxide-based dielectric layer with a desired thickness 162t, may be formed on the dielectric layer 161, thereby forming an interface 163f therewith. As discussed above, the hafnium oxide-based layer 162 may have a thickness that may be adjusted with high precision on the basis of the number of total cycles applied, wherein the superior two-dimensional growth may result in superior interface characteristics compared to a conventionally manufactured hafnium oxide-based dielectric material with the same thickness. Furthermore, in some illustrative embodiments as discussed above, the high-k dielectric layer 162 may have a material composition that substantially complies with the stoichiometric formula of hafnium dioxide, while in other cases a certain deviation from the stoichiometric ratio of hafnium dioxide may be adjusted wherein, however, only insignificant amounts of silicon and nitrogen may be present. The dielectric layer 161 and the high-k dielectric layer 162 thus form, in combination, a dielectric material or material system 163, which may be used as a capacitor dielectric layer, a gate dielectric layer and the like. Thus, the layer 163 may provide a physical thickness that is appropriate for retaining corresponding leakage currents at an acceptable level, while nevertheless providing a k value and thus capacitive coupling that is comparable to an extremely thin silicon dioxide layer. For example, by adjusting the thickness of the layer 161 to a value of 0.8 nm and less, while selecting the thickness 162t of the hafnium-based high-k dielectric material to be 3 nm and less, a silicon dioxide equivalent thickness of 1.2 nm and less may be obtained, however, with leakage current levels that are significantly higher compared to a silicon dioxide layer having a thickness of 1.2 nm and less. Furthermore, the dielectric layer 163 may have superior reliability and a higher breakdown voltage compared to a conventionally manufactured dielectric material having substantially the same material composition, which is seen to be caused by the surface treatment 104 (FIG. 1b).

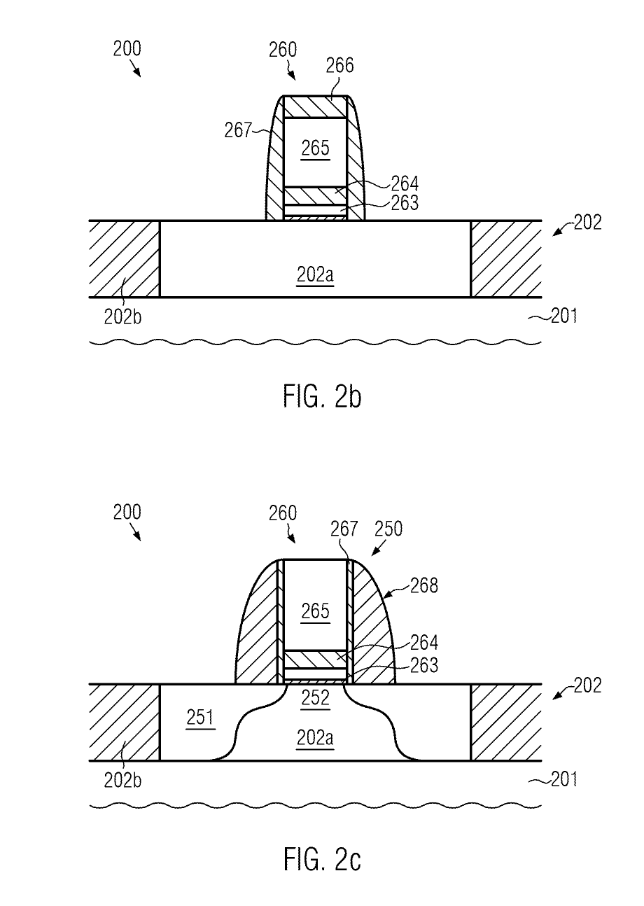

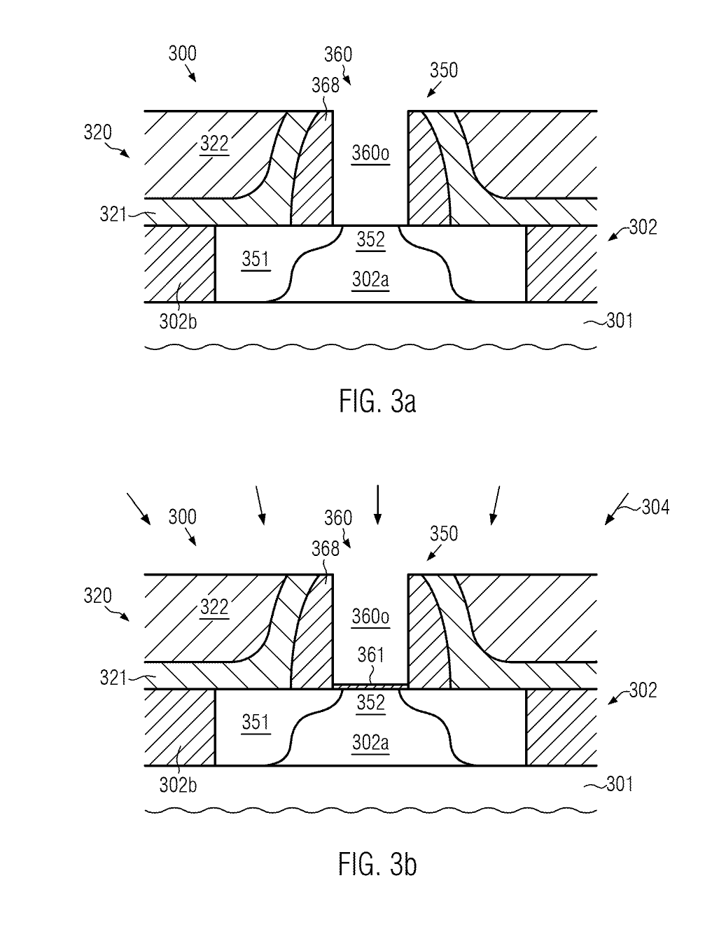

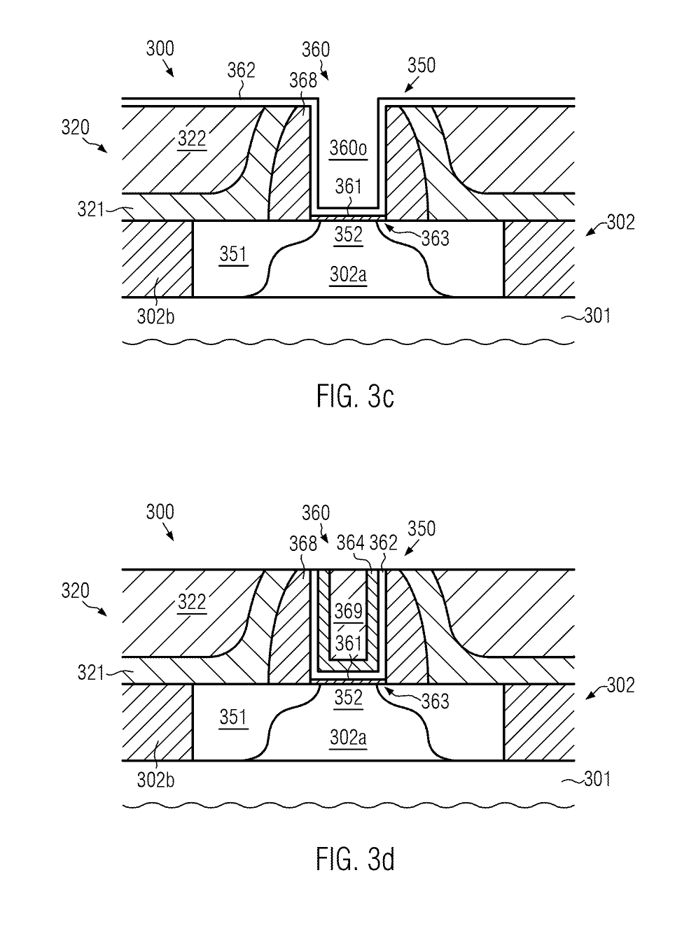

The manufacturing sequence described above and the resulting dielectric material 163 may be efficiently used for being incorporated in circuit elements, such as capacitors, transistors and the like. In the following further illustrative embodiments which are described in the context of FIGS. 2a-2c and 3a-3d, sophisticated transistors will be described in which gate electrode structures may be provided on the basis of a hafnium oxide-based high-k dielectric material. It should be appreciated, however, that the superior hafnium oxide-based high-k dielectric material in combination with the underlying conventional dielectric material may also be used in capacitors and the like.

FIG. 2a schematically illustrates a cross-sectional view of a semiconductor device 200 comprising a substrate 201 and a semiconductor layer 202 in which an active region 202a may be laterally delineated by an isolation structure 202b. With respect to these components, it should be appreciated that the same criteria may apply as previously discussed with reference to the device 100. Moreover, in the manufacturing stage shown, a gate layer stack 260s may be formed above the active region 202a and may comprise a dielectric material or layer 263, which in turn may be comprised of a first dielectric layer 261 and a second hafnium oxide-based high-k dielectric layer 262, in combination with one or more electrode materials 264, 265, possibly followed by any appropriate cap material or material system 266. It should be appreciated that the dielectric layer 263, which may represent a gate dielectric layer, may have any appropriate configuration as required for the gate electrode structure to be formed from the gate layer stack 260s in a later manufacturing stage. For example, the layers 261 and 262 may have characteristics as discussed above with reference to the layers 161 and 162 of the device 100. Consequently, superior interface characteristics at an interface 263f between the layers 261 and 262 may be obtained, which in turn may result in superior performance characteristics and enhanced reliability of the resulting gate electrode structure.

The device 200 as shown in FIG. 2a may be formed on the basis of process techniques as are also discussed above with reference to the semiconductor device 100. That is, the components 202a, 202b and the dielectric material layer 263 may be formed in accordance with process strategies as described above. It should be appreciated that, in particular, the active region 202a in some device areas may comprise a silicon/germanium alloy (not shown) or any other semiconductor alloy so as to provide for a shift of the resulting threshold voltage, as may be required for some types of transistors to be formed. After completing the hafnium oxide-based high-k dielectric layer 262 on the basis of a cyclic deposition process, as discussed above, the processing may be continued by forming the electrode material 264, for instance in the form of tantalum nitride, titanium nitride and the like. To this end, depending on the overall process strategy, one or more deposition and patterning processes may be applied so as to form a work function metal layer, for instance in the form of an aluminum layer, a lanthanum layer and the like, in combination with an appropriate metal-containing material above the active region 202a, depending on the conductivity type of a transistor to be formed in and above the active region 202a. It should further be appreciated that the adjustment of an appropriate work function may include the diffusion of an appropriate work function metal species into the material 262 and possibly to the interface 263f, wherein the superior interface characteristics may also result in superior process robustness upon adjusting work function of the gate layer stack 260s and thus threshold voltage of a transistor still to be formed. Thereafter, the electrode material 265, for instance in the form of silicon, silicon/germanium and the like, may be deposited on the basis of well-established deposition techniques, followed by the deposition of one or more sacrificial materials, such as the layer or layer system 266. Next, sophisticated lithography and patterning strategies may be applied in order to form an appropriate etch mask, for instance from the sacrificial material 266, which may then be used for patterning the gate layer stack 260s.

FIG. 2b schematically illustrates the device 200 in a further advanced manufacturing stage. As shown, a gate electrode structure 260 may be formed on the active region 202a and may comprise the gate dielectric material 263 and the electrode materials 264, 265, followed by the cap layer 266. These materials may have any appropriate lateral dimension so as to comply with the design rules. For example, a gate length may be 50 nm and significantly less. Moreover, in the manufacturing stage shown, a spacer or liner 267 may be provided on sidewalls of the materials 263, 264, 265 so as to particularly protect the sensitive materials 263 and 264 during the further processing of the device 200. For example, in sophisticated applications, a strain-inducing semiconductor alloy (not shown), such as a silicon/germanium alloy, a silicon/carbon alloy and the like, may be incorporated into at least some of the active regions 202a in order to enhance overall performance of a corresponding transistor. During a corresponding process sequence, the spacer 267 may preserve integrity of the sensitive materials 263 and 264. Similarly, during any further processes for completing the basic transistor configuration, the spacer 267 may preserve integrity of these materials and may thus provide superior robustness and stability of the resulting transistor characteristics.

FIG. 2c schematically illustrates the semiconductor device 200 in a further advanced manufacturing stage. As shown, a transistor 250 may be formed in and above the active region 202a and may comprise drain and source regions 251, which laterally enclose a channel region 252, above which the gate electrode structure 260 may be formed and may thus control current flow through the channel region 252. The gate electrode structure 260 may comprise the materials 263, 264, 265, as discussed above, in combination with an appropriately dimensioned spacer structure 268, which may be used for defining the lateral and vertical profile of the drain and source regions 251. The transistor 250 may be formed on the basis of any appropriate process strategy, which may include the incorporation of any strain-inducing materials (not shown), if required, and the formation of the drain and source regions 251, for instance by implantation processes, epitaxial growth techniques and the like. Moreover, any high temperature processes may be applied, if required, so as to adjust the final lateral and vertical profile of the drain and source regions 251. Due to the superior characteristics of the dielectric layer 263, as discussed above, the previously adjusted electronic characteristics may not be unduly affected, thereby providing superior device uniformity and stability. Furthermore, generally superior performance of the transistor 250 may be obtained, as will be discussed later on in more detail.

It should be appreciated that, in some illustrative embodiments, the electrode material 265 may be removed in a later manufacturing stage, for instance after forming a corresponding contact level and selectively removing the material 265 on the basis of well-established selective etch recipes. Thereafter, at least one further highly conductive electrode material, such as a metal or metal alloy, may be deposited, thereby even further enhancing performance of the resulting gate electrode structure 260.

It should be appreciated that the superior characteristics of the hafnium oxide-based high-k dielectric material in combination with the underlying conventional dielectric material may allow a highly efficient adjustment of transistor characteristics in an early manufacturing stage. In other cases, the gate dielectric layer including a hafnium oxide-based high-k dielectric material may be provided in a late manufacturing stage, i.e., after the completion of the actual transistor configuration, by applying a so-called replacement gate approach.

FIG. 3a schematically illustrates a cross-sectional view of a semiconductor device 300 in an advanced manufacturing stage. As shown, a transistor 350 may be formed in and above an active region 302a, which in turn is laterally delineated by isolation regions 302b in a semiconductor layer 302. The layer 302 may be formed above a substrate 301 so as to form an SOI architecture or a bulk configuration, as is also discussed above with reference to the device 100. In the manufacturing stage shown, the transistor 350 may comprise drain and source regions 351 and a channel region 352, the lateral and vertical dopant profile of which may be substantially defined by any previously performed processes, such as implantation and anneal processes. Furthermore, a gate electrode structure 360 may be provided so as to act as a replacement gate structure, which may serve to complete the basic transistor configuration and to define the lateral dimensions of the gate electrode structure 360, wherein the electronic characteristics thereof are still to be adjusted by providing an appropriate gate dielectric material in combination with one or more electrode materials. To this end, the gate electrode structure 360 may comprise a corresponding gate opening or gate trench 360o, the lateral dimensions of which are substantially defined by a spacer structure 368. Moreover, the transistor 350 and thus the gate electrode structure 360 may be laterally embedded in a contact level 320, which may comprise a dielectric layer 321, such as a silicon nitride layer, in combination with a further dielectric layer 322, such as a silicon dioxide layer and the like.

The transistor 350 may be formed on the basis of any appropriate process strategy wherein the gate electrode structure 360 may be formed in an early manufacturing stage so as to comply with the design rule terms of lateral dimensions, followed by formation of the drain and source regions 351 using any appropriate process strategy. Thereafter, the contact level 320 may be formed by deposition and planarization techniques, wherein also a placeholder material (not shown), such as a polysilicon material and the like, of a gate electrode structure 360 may be exposed. Thereafter, a selective etch process may be applied so as to form the gate opening 360o, wherein a dielectric material, such as silicon dioxide and the like (not shown), may be used as an etch stop layer, which may be subsequently removed on the basis of highly selective etch recipes. Hence, in the embodiment shown, a surface portion of the active region 302a may be exposed so as to enable the formation of a first dielectric layer in the form of a thin “conventional” base layer.

FIG. 3b schematically illustrates the semiconductor device 300 in a further advanced manufacturing stage. As shown, a first dielectric layer 361, such as a silicon dioxide layer and the like, may be formed on the exposed portion of the active region 302a within the gate opening 360o. The layer 361 may be formed on the basis of wet chemical oxidation recipes in order to form a well-defined silicon dioxide material or silicon/germanium oxide material with precisely controlled thickness in the range of 1 nm and significantly less, as is also discussed above. Thereafter, a surface treatment or wet chemical process 304 may be applied, similar to the process 104 as discussed above with reference to FIG. 1b, so as to prepare a surface of the layer 361 for a subsequent cyclic deposition process. For example, an ammonium hydroxide/hydrogen peroxide mixture may be applied at room temperature so as to provide superior growth conditions during the subsequent deposition process. The deposition of a hafnium oxide-based material may be accomplished in a similar manner as described above with reference to the device 100, thereby enabling precise definition of the resulting layer thickness.

FIG. 3c schematically illustrates the semiconductor device 300 after forming a hafnium oxide-based high-k dielectric material 362, which may form in combination with the dielectric layer 361a gate dielectric layer 363 having superior interface characteristics, as is also explained above. It should be appreciated that any interface characteristics of the layer 362 and any other dielectric material outside the dielectric layer 361 are less relevant for the overall characteristics of the gate electrode structure 360.

FIG. 3d schematically illustrates the semiconductor device 300 in a further advanced manufacturing stage. As illustrated, the gate electrode structure 360 may comprise the gate dielectric layer 363 comprised of the dielectric layers 361 and 362, wherein the layer 362 may also be provided on inner sidewall areas of the gate electrode structure 360. Moreover, a first electrode material 364, which may be appropriately selected so as to obtain a desired work function, may be provided, for instance in the form of titanium nitride, tantalum nitride or any combination thereof, possibly with an appropriate work function metal layer. Moreover, a highly conductive further electrode material 369, such as aluminum, aluminum alloy and the like, may be formed in the gate electrode structure 360, thereby imparting superior conductivity to the structure 360. The gate electrode structure 360 as shown in FIG. 3d may be formed on the basis of appropriate deposition strategies for providing the material 364, which may include the deposition of different material layers and the patterning of at least some of these material layers, in order to provide an appropriately composed material 364 or a respective type of gate electrode structure. Thereafter, the material 369 may be deposited on the basis of any appropriate deposition recipe and excess material may be removed, for instance, by applying any appropriate planarization technique.

Consequently, the gate dielectric material 363 having the superior interface characteristics may also be applied in the context of a replacement gate approach, thereby providing superior flexibility in forming sophisticated high-k metal gate electrode structures.

As discussed above, the superior characteristics of a gate dielectric material or a capacitor dielectric material may result in superior overall performance of the associated circuit element.

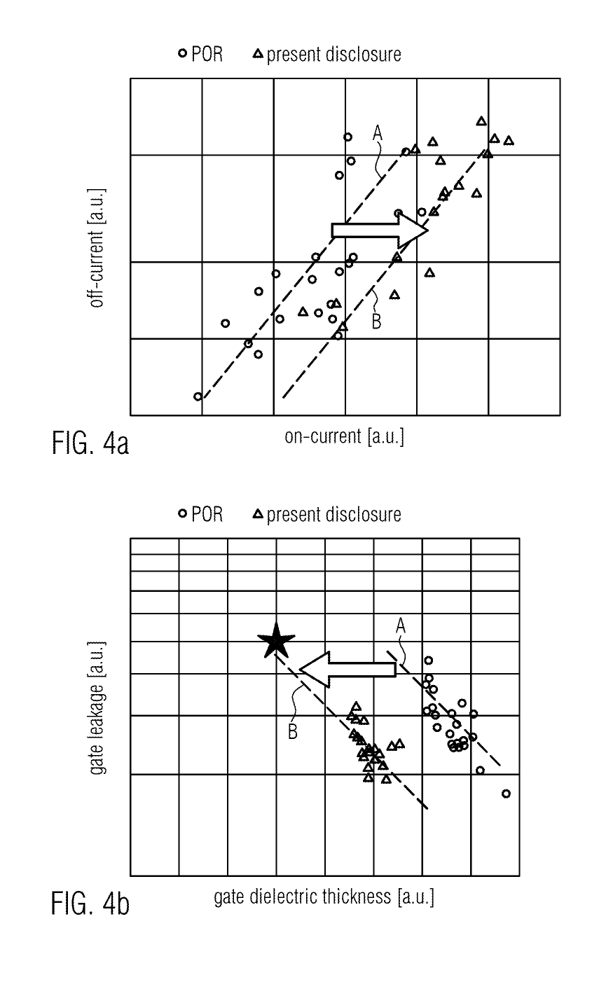

FIG. 4a schematically illustrates a graph depicting measurement results that correspond to N-channel transistor devices formed in accordance with the process techniques described above with reference to the transistors 250 or 350 (FIG. 2c and FIG. 3d, respectively) in comparison with respective transistors formed on the basis of a conventional strategy, i.e., without providing a gate dielectric material of superior characteristics. In FIG. 4a, measurement points corresponding to conventional devices are indicated by curve A, while the transistors according to the present disclosure are indicated by curve B. In FIG. 4a, a typical graph for representing performance of transistors is illustrated in which the off current in arbitrary units is plotted along the vertical axis, while the on current of the transistors is plotted along the horizontal axis in arbitrary units. As shown, compared to conventional devices, the transistors of the present disclosure generally exhibit higher on currents for a given off current value, thereby indicating a significant performance improvement.

FIG. 4b is a graph in which the gate leakage currents are plotted along the vertical axis, while the effective thickness of a gate dielectric layer is plotted along the horizontal axis, wherein both axes are labeled according to arbitrary units. As is evident from FIG. 4b, for the same gate leakage level, the effective thickness of the gate dielectric material is less compared to the conventional transistors, thereby indicating an increased capacitive coupling for a given gate leakage current. That means that, generally, a reduced physical thickness may be used as well to further enhance the capacitive coupling between a gate electrode and the channel region of a transistor, without increasing the resulting gate leakage currents. In other cases, for a given physical thickness of the gate dielectric layer, a reduced gate leakage level may be accomplished, thereby significantly improving performance and reliability of the transistors. That is, upon implementing a given physical thickness of the gate dielectric material including the hafnium oxide-based high-k dielectric material, an increased dielectric breakdown voltage and reduced threshold shifts caused by hot carrier injection and the like may be observed in transistor devices formed in accordance with the principles disclosed herein.

As a result, the present disclosure provides manufacturing techniques in which reliability of devices with high-k metal dielectric material is enhanced by improving characteristics of an interface between a conventional dielectric material, such as a silicon dioxide-based material, and a hafnium oxide-based high-k dielectric material. To this end, it has been recognized that a surface treatment prior to the ALD process may significantly enhance the growth conditions by promoting the two-dimensional growth of the hafnium-based oxide material. When applying the combined dielectric material to a transistor or a capacitor, significantly enhanced performance and increased reliability may be achieved. In addition, overall superior process robustness may be achieved since the combined dielectric material is less sensitive to influences caused by high temperature and/or oxygen-related process steps, which are typically required for forming complex transistors or capacitors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first dielectric layer on a semiconductor region of a semiconductor device;
performing a surface treatment on said first dielectric layer by using a mixture of ammonium hydroxide and hydrogen peroxide so as to prepare a surface of said first dielectric layer for a subsequent deposition of a second dielectric layer based on hafnium oxide; and
forming said second dielectric layer on said prepared surface by applying a cyclic deposition process.

2. The method of claim 1, wherein forming said first dielectric layer comprises forming a silicon and oxygen-containing dielectric material on said semiconductor region.

3. The method of claim 1, wherein forming said second dielectric layer comprises performing said cyclic deposition process on the basis of substantially silicon-free precursor gases.

4. The method of claim 1, wherein performing said surface treatment comprises selecting a process temperature to be in the range of 10-40° C.

5. The method of claim 4, wherein said process temperature is selected to be in the range of 15-30° C.

6. The method of claim 1, wherein applying said cyclic deposition process comprises repeating a sequence of process steps including exposing said prepared surface to a hafnium-containing precursor and an oxidant-containing precursor with an intermediate purge step.

7. The method of claim 1, wherein said first dielectric layer is formed with a thickness of 1 nm or less.

8. The method of claim 1, wherein said second dielectric layer is formed with a thickness of 3 nm or less.

9. The method of claim 1, further comprising forming a gate electrode structure of a transistor by using said first and second dielectric layers as a gate insulation layer.

10. The method of claim 1, further comprising forming a capacitor by using said first and second dielectric layers as a capacitor dielectric.

11. A method, comprising:
forming an oxide-based dielectric layer on an active region of a transistor of a semiconductor device;
preparing a surface of said oxide-based dielectric layer for a subsequent deposition of a hafnium oxide-based high-k dielectric material by performing a wet chemical treatment so as to increase a number of OH groups at said surface;
forming said hafnium oxide-based high-k dielectric material by a cyclic deposition process; and
forming a gate electrode structure of said transistor by forming at least one electrode material above said hafnium oxide-based high-k dielectric material.

12. The method of claim 11, wherein performing a wet chemical treatment so as to increase a number of OH groups at said surface comprises applying a mixture of ammonium hydroxide and hydrogen peroxide.

13. The method of claim 12, wherein said wet chemical treatment is performed with a process temperature in the range of 10-40° C.

14. The method of claim 11, wherein forming said gate electrode structure comprises forming a gate layer stack including said oxide-based dielectric layer, said hafnium oxide-based high-k dielectric material and said at least one electrode material and patterning said gate layer stack.

15. The method of claim 11, wherein forming said gate electrode structure comprises forming said hafnium oxide-based high-k dielectric material prior to forming drain and source regions of said transistor and forming one or more of said at least one electrode material after forming said drain and source regions.

16. The method of claim 11, wherein forming said gate electrode structure comprises forming said hafnium oxide-based high-k dielectric material and said at least one electrode material after forming drain and source regions of said transistor.

17. The method of claim 11, wherein applying said cyclic deposition process comprises using silicon-free precursor gases so as to form said hafnium oxide-based high-k dielectric material as a substantially silicon-free dielectric material.

18. The method of claim 11, wherein said oxide-based dielectric layer is formed as a silicon-containing oxide material.

19. A method of forming a gate dielectric material of a transistor, the method comprising:
forming an oxide-based dielectric material on an active region of said transistor;
preparing a surface of said oxide-based dielectric material by applying a wet chemical process based on ammonium hydroxide and hydrogen peroxide; and
forming a hafnium oxide layer on said prepared surface while suppressing incorporation of non-hafnium species and non-oxygen species.

20. The method of claim 19, wherein said wet chemical process is applied with a process temperature in the range of 15-30° C.
